(19) United States
(12) Patent Application Publication
(10) Pub. No.: US 2019/0237307 A1
(43) Pub. Date: Aug. 1, 2019

(54) SUPPORT TABLE, SUBSTRATE PROCESSING APPARATUS, SUBSTRATE PROCESSING SYSTEM, AND SUPPORT MANUFACTURING METHOD

(71) Applicant: TOKYO ELECTRON LIMITED, Tokyo (JP)

(72) Inventor: Yasuharu SASAKI, Miyagi (JP)

(73) Assignee: TOKYO ELECTRON LIMITED, Tokyo (JP)

(21) Appl. No.: 16/259,189

(22) Filed: Jan. 28, 2019

(30) Foreign Application Priority Data
Jan. 29, 2018 (JP) 2018-012743

(51) Int. Cl. H01J 37/32; H01L 21/677; H01L 21/683; H01L 21/67

(52) U.S. Cl. CPC H01J 37/32715; H01J 37/32192; H01L 21/67103; H01L 21/6833; H01L 21/67739

(57) ABSTRACT

A support table according to an embodiment includes a base and a support. The support is provided on the base. The support has a main body and a conductive film. The main body is formed of a dielectric material. The body has a surface region and a rear surface. The surface region is a region that is in contact with a rear surface of the substrate placed on the support. The rear surface is a surface opposite to the surface region. The rear surface of the support is bonded to the base. The conductive film is spaced apart from the surface region, and has an undulation. The surface region extends along the conductive film.

### CROSS-REFERENCE TO RELATED APPLICATIONS

This application is based on and claims priority from Japanese Patent Application No. 2018-012743, filed on Jan. 29, 2018, with the Japan Patent Office, the disclosures of which are incorporated herein in their entireties by reference.

### TECHNICAL FIELD

Exemplary embodiments of the present disclosure relate to a support table, a substrate processing apparatus, a substrate processing system, and a support manufacturing method.

### BACKGROUND

In manufacturing an electronic device, a substrate is processed using a substrate processing apparatus. The substrate is processed in the state of being mounted on a support table in a chamber of the substrate processing apparatus. The support table includes a base and an electrostatic chuck.

The electrostatic chuck is provided on the base. The electrostatic chuck has a dielectric material and an electrode. The electrode is provided in the dielectric material. When a DC voltage is applied to the electrode, an electrostatic attractive force is generated between the substrate and the electrostatic chuck. Due to the generated electrostatic attractive force, the substrate is attracted to the electrostatic chuck and held by the electrostatic chuck. Such a support table is described in Japanese Patent Laid-open Publication No. 2017-208565.

### SUMMARY

In a first aspect, a support table is provided. The support table base includes a base and a support. The support is provided on the base. The support has a main body and a conductive film. The main body is formed of a dielectric material. The body has a surface region and a rear surface. The surface region is a region that is in contact with a rear surface of the substrate placed on the support. The rear surface is a surface opposite to the surface region. The rear surface of the support is bonded to the base. The conductive film is spaced apart from the surface region, and has an undulation. The surface region extends along the conductive film.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating a support table according to an embodiment.

FIG. 2 is a cross-sectional view schematically illustrating a substrate processing apparatus according to an embodiment.

FIG. 3 is a view schematically illustrating a substrate processing system according to an embodiment.

FIG. 4 is a flow flowchart illustrating an embodiment of a substrate manufacturing method.

FIGS. 5A, 5B, 5C, and 5D are views each illustrating a product prepared in the steps of the method illustrated in FIG. 4.

FIGS. 6A, 6B, and 6C are views each illustrating a product prepared in the steps of the method illustrated in FIG. 4.

FIGS. 7A, 7B, 7C, and 7D are views each illustrating a product prepared in the steps of the method illustrated in FIG. 4.

FIG. 8 is a flow chart illustrating another embodiment of the support manufacturing method.

FIGS. 9A, 9B, 9C, and 9D are views each illustrating a product prepared in the steps of the method illustrated in FIG. 8.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

A substrate may not be flat but may be warped. When a pattern formed on a substrate is a complicated pattern, the rear surface of the substrate has a complicated shape due to the warpage of the substrate. When a warped substrate is held by the electrostatic chuck, portions, which are not in contact with the surface region of the electrostatic chuck, occurs on the rear surface of the substrate. As a result, in-plane uniformity of a substrate processing may be impaired. Such a problem may also occur in a substrate support table other than the electrostatic chuck. Under this background, it is required to reduce the number of spots in the rear surface of the substrate, which are not in contact with the surface region of the support table, even if the substrate is warped.

In a first aspect, a support table is provided. The support table base includes a base and a support. The support is provided on the base. The support has a main body and a conductive film. The main body is formed of a dielectric material. The body has a surface region and a rear surface. The surface region is a region that is in contact with a rear surface of the substrate placed on the support. The rear surface is a surface opposite to the surface region. The rear surface of the support is bonded to the base. The conductive film is spaced apart from the surface region, and has an undulation. The surface region extends along the conductive film.

In the support table according to the first aspect, since the rear surface of the support is bonded to the base, uniform heat exchange is performed between the substantially entire rear surface of the support and the base. Therefore, in this support table, the uniformity of the temperature distribution of the support is high. In addition, the surface region extends along the conductive film having an undulation. That is, the surface region extends so as to provide a surface having an undulation. The shape of this surface region may be made to match or correspond to the shape of the rear surface of the substrate. Therefore, according to this support table, the number of spots in the rear surface of the substrate, which are not in contact with the surface region of the support table, decreases. In addition, in this support table, the distance between the conductive film and the surface region is substantially constant. Accordingly, uniform heat exchange is performed between the substantially entire rear surface of the substrate and the surface region. Therefore, the substrate processing performed in the state where the substrate W is supported by the support table 10 has high in-plane uniformity.

In an embodiment, the conductive film and the surface region may extend to be at least partially curved.

In an embodiment, the rear surface of the support and the base may be bonded to each other via a bonding material. The bonding material may be an adhesive or a soldering material.

In an embodiment, the conductive film is configured to apply a voltage thereto so as to generate an electrostatic attractive force. The support in this embodiment is an electrostatic chuck. As described above, the distance between the conductive film and the surface region is substantially constant. Accordingly, an electrostatic attractive force is generated substantially uniformly between the support, that is, the electrostatic chuck, and the substantially entire rear surface of the substrate. Therefore, according to the support table of this embodiment, uniform heat exchange is performed between the substantially entire rear surface of the substrate and the surface region.

In a second aspect, a substrate processing apparatus is provided. The substrate processing apparatus includes a chamber and a support table. The support table is the support table according to the first aspect or any one of the above-mentioned embodiments. The support table is configured to support a substrate in the chamber.

In a third aspect, a substrate processing system is provided. The substrate processing system includes a plurality of process modules and a transport module. The transport module includes a transport device. The transport device is configured to transport a substrate to the plurality of process modules. Each of the plurality of process modules includes a chamber and a support table. The support table is the support table according to the first aspect or any one of the above-mentioned embodiments. The support table is configured to support a substrate in the chamber. The surface region of the support table of each of the plurality of process modules has a shape that is different from that of the surface region of the support table of at least one other process module among the plurality of process modules.

In the substrate processing system according to the third aspect, the shape of the surface region of the support table of each of the plurality of process modules may be formed to match or correspond to the shape of the rear surface of a substrate to be supported thereon. Accordingly, the number of spots in the rear surface of the substrate, which do not in contact with the surface region of the support table of each of the plurality of process modules, decreases. Therefore, in each of the plurality of process modules, a substrate processing having high in-plane uniformity is capable of being realized.

In a fourth aspect, a method for manufacturing a substrate support is provided. This method includes (i) providing an unfired body and (ii) firing the unfired body. The unfired body has a first region and a second region. The first region is formed of a dielectric material. The second region is provided in the first region. The second region is conductive and has an undulation.

According to the method according to the fourth aspect, the main body of the support is formed from the first region, and the conductive film of the support having an undulation is formed from the second region.

In an embodiment, in the step of firing the unfired body, the unfired body is fired through a hot press method. In this embodiment, the step of providing the unfired body includes (a) forming a first intermediate product in the container by providing raw material powder as the dielectric raw material in the container; (b) forming a second intermediate product having a surface including an undulation by pressing a mold against the first intermediate product; (c) forming a third intermediate product by providing a conductive raw material on the surface of the second intermediate product in the container; and (d) forming a fourth intermediate product by providing the raw material powder on the surface of the third intermediate product in the container. The unfired body is the fourth intermediate product or is formed of the fourth intermediate product. According to this embodiment, a conductive film having an undulation is formed by using a mold that matches to or corresponds to the shape of the rear surface of the substrate.

In an embodiment, the method further includes a step of measuring the shape of the rear surface of the substrate. The surface of the mold is formed according to the measured shape.

In an embodiment, the step of providing the unfired body further includes forming a fifth intermediate product in the container by pressing the mold or another mold against the fourth intermediate product. The fifth intermediate product has a surface extending along a region formed of the conductive raw material. In this embodiment, the unfired body is the fifth intermediate product. According to this embodiment, the surface region of the above-mentioned support is formed from the surface of the fifth intermediate product by firing the fifth intermediate product.

In an embodiment, the unfired body is the fourth intermediate product. In this embodiment, the method further includes processing a surface of a fired body formed by firing of the unfired body. In the step of processing the surface of the fired body, the surface of the fired body is processed so as to provide a surface region extending along a conductive film formed of the conductive raw material.

In an embodiment of the step of providing the unfired body, a sheet including a third region and a fourth region is provided. The third region is formed of a dielectric material. The fourth region is conductive and is formed in the third region. A sheet material is placed on the surface of the mold such that the first region is formed from the third region and the second region is formed from the fourth region. The surface of the mold has an undulation corresponding to the undulation of the second region. In this embodiment, the second region having the undulation is formed by providing the sheet material on the surface of the mold. In addition, a support is formed by firing the sheet material having the first region and the second region.

In an embodiment, the method further includes measuring the shape of the rear surface of the substrate, and the surface of the mold is formed according to the measured shape.

As described above, it is possible to reduce the number of spots in the rear surface of the substrate, which are not in contact with the surface region of the support table, even if the substrate is warped.

Hereinafter, various embodiments will be described in detail with reference to the drawings. In respective drawings, the same or corresponding parts will be denoted by the same reference numerals.

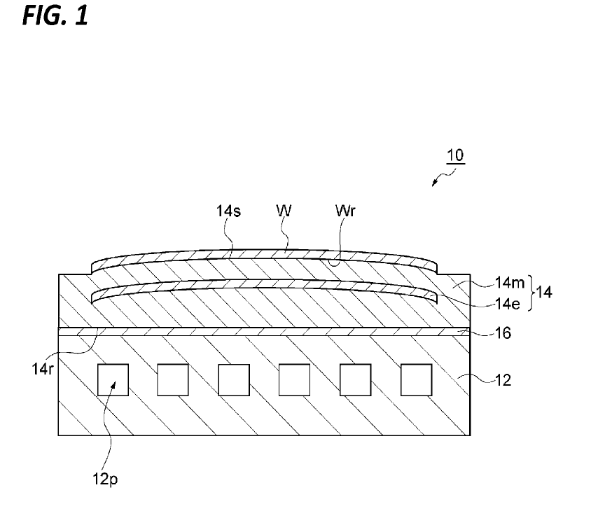

FIG. 1 is a cross-sectional view illustrating a support table according to an embodiment. The support table 10 illustrated in FIG. 1 is configured to support a substrate W placed thereon. The support table 10 includes a base 12 and a support 14. The base 12 has a function of supporting the support 14 and a function of performing heat exchange with the support 14. In an embodiment, a flow path 12p is formed in the base 12. The flow path 12p may extend in the base 12, for example, in a spiral shape. A heat exchange medium is supplied to the flow path 12p. The heat exchange medium supplied to the flow path 12p is discharged from the flow path 12p to the outside of the base 12. The base 12 is formed of, for example, aluminum, although it is not limited.

The support 14 is provided on the base 12. The support 14 has a main body 14m and a conductive film 14e. The main body 14m has a substantially plate-like shape. The main body 14m is formed of a dielectric material. The main body 14m is formed of a ceramic such as, for example, an aluminum oxide or an aluminum nitride.

The support 14 has a surface region 14s and a rear surface 14r. The surface region 14s is a region that is in contact with a rear surface Wr of the substrate W placed on the support 14. The surface region 14s may be formed of a continuous surface or a plurality of discrete surfaces. The discrete surfaces are constituted by the tops of a plurality of convex portions provided on the upper surface side of the support 14.

The rear surface 14r is a surface opposite to the surface region 14s. The rear surface 14r is bonded to the base 12. The entire region of the rear surface 14r extending at least between the surface region 14s and the base 12 or the entire rear surface 14r is bonded to the base 12. In an embodiment, the rear surface 14r is bonded to the base 12 via a bonding material 16. The bonding material 16 is provided between the entire region of the rear surface 14r, which extends at least between the surface region 14s and the base 12, and the base 12. The bonding material 16 may be provided between the entire rear surface 14r and the base 12. The bonding material 16 is, for example, an adhesive. The bonding material 16 may be a soldering material. Alternatively, the support 14 may be fixed to the base 12 by electrostatic attraction.

The conductive film 14e is provided in the main body 14m. The conductive film 14e is a film having conductivity. In an embodiment, the conductive film 14e is an electrode to which a DC voltage is applied in order to generate an electrostatic attractive force between the support 14 and the substrate W. In this embodiment, the support 14 is an electrostatic chuck. In another embodiment, the conductive film 14e is a heater (resistive heating element). In the case where the support 14 is an electrostatic chuck, the support 14 may have a heater (resistive heating element) therein, in addition to the electrode to which the direct voltage is applied.

The conductive film 14e is spaced apart from the surface region 14s on the base 12 side. The conductive film 14e has an undulation. The undulation shape of the conductive film 14e is formed so as to match or correspond to the shape of the rear surface Wr of the substrate W. The surface region 14s extends along the conductive film 14e. That is, the surface region 14s extends to provide a surface having an undulation. The undulation shape of the conductive film 14s is formed so as to match or correspond to the shape of the rear surface Wr of the substrate W. In the case where the surface region 14s is constituted by a plurality of discrete surfaces, a virtual continuous surface including the discrete plurality of discrete surfaces provides an undulation. The magnitude of the undulation of each of the conductive film 14e and the surface region 14s is larger than the size of the unevenness determined by the particles constituting each of the conductive film 14e and the surface region 14s. In addition, in the case where the surface region 14s is constituted by the tops of a plurality of protrusions, the undulation of each of the conductive film 14e and the surface region 14s is an undulation separate from the plurality of protrusions.

In an embodiment, each of the conductive film 14e and the surface region 14s extends to be at least partially curved. For example, each of the conductive film 14e and the surface region 14s may have a shape in which the position in the height direction increases from the edge toward the center, that is, a convex shape. Alternatively, each of the conductive film 14e and the surface region 14s may have a shape in which the position in the height direction decreases from the edge toward the center, that is, a concave shape. Alternatively, each of the conductive film 14e and the surface region 14s may have a complicated shape including a plurality of irregularities. The size of the undulation of each of the conductive film 14e and the surface region 14s, that is, the distance difference in the height direction between the highest position and the lowest position of each of the conductive film 14e and the surface region 14s is larger than, for example, 100 μm. The size of the undulation of each of the conductive film 14e and the surface region 14s is smaller than, for example, 500 μm.

In the support table 10 described above, since the rear surface 14r of the support 14 is bonded to the base 12, uniform heat exchange is performed between substantially the entire rear surface 14r of the support 14 and the base 12. Therefore, in the support table 10, the uniformity of temperature distribution of the support 14 is high. In addition, the surface region 14s extends along the conductive film 14e having an undulation. That is, the surface region 14s extends to provide a surface having an undulation. The shape of the conductive film 14s may be formed so as to match or correspond to the shape of the rear surface Wr of the substrate W. Therefore, according to the support table 10, even if the substrate W is warped, the number of spots in the rear surface Wr of the substrate W, which are not in contact with the surface region 14s of the support 14, decreases. In addition, in the support table 10, the distance between the conductive film 14e and the surface region 14s is substantially constant. Therefore, uniform heat exchange is performed between the substantially entire rear surface Wr of the substrate W and the surface region 14s. Therefore, the substrate processing performed in the state where the substrate W is supported by the support table 10 has high in-plane uniformity.

In an embodiment, the support 14 is an electrostatic chuck. As described above, the distance between the conductive film 14e and the surface region 14s is substantially constant. Therefore, an electrostatic attractive force is generated substantially uniformly between the support 14, that is, the electrostatic chuck, and the substantially entire rear surface Wr of the substrate W. Therefore, according to the support table 10, uniform heat exchange is performed between the substantially entire rear surface Wr of the substrate W and the surface region 14s.

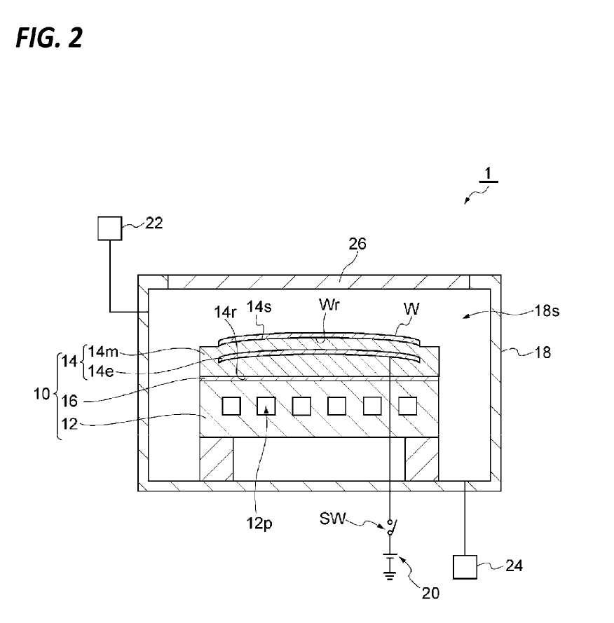

Hereinafter, a substrate processing apparatus according to an embodiment will be described. FIG. 2 is a cross-sectional view schematically illustrating a substrate processing apparatus according to an embodiment. The substrate processing apparatus 1 illustrated in FIG. 2 includes a support table 10 and a chamber 18. The support table 10 is provided in the chamber 18, that is, in an internal space 18s provided by the chamber 18.

A heat exchange medium (e.g., a coolant) is supplied to the flow path 12p of the base 12 of the support table 10 from a supply device (e.g., a chiller unit) provided outside the chamber 18. The heat exchange medium supplied to the flow path 12p is returned to the supply device. That is, a heat exchange medium is circulated between the flow path 12p and the supply device. The temperature of the base 12 is adjusted by the heat exchange medium, and the temperature of the substrate W is adjusted by heat exchange between the base 12 and the support 14 and heat exchange between the support 14 and the substrate W.

In an embodiment, the support 14 is an electrostatic chuck. In this embodiment, the conductive film 14e of the support 14 is electrically connected to a DC power supply 20 via a switch SW. The DC power supply 20 generates a DC voltage. When a DC voltage is applied from the DC power supply 20 to the conductive film 14e, an electrostatic attractive force is generated between the support 14 and the substrate W. In another embodiment, the conductive film 14e is a heater (resistive heating element). In this embodiment, a heater power supply is electrically connected to the conductive film 14e.

In an embodiment, the substrate processing apparatus 1 may further include a gas supply unit 22. The gas supply unit 22 supplies the gas used in a processing for a substrate W, that is, a substrate processing, to the internal space 18s. In an embodiment, the substrate processing apparatus 1 may further include an exhaust device 24. The exhaust device 24 is configured to evacuate the gas in the internal space 18s so as to reduce the pressure in the internal space 18s. The exhaust device 24 has, for example, a pressure regulating valve and a decompression pump. The decompression pump may include one or more pumps, such as, for example, a turbo-molecular pump and a dry pump.

The processing performed on the substrate W in the substrate processing apparatus 1 may be any substrate processing. In an embodiment, the substrate processing apparatus 1 is configured to perform a plasma processing on the substrate W. In this embodiment, the substrate processing apparatus 1 includes a plasma generation unit 26. The plasma generation unit 26 is configured to supply energy for exciting the gas in the internal space 18s. The plasma generation unit 26 may be any type of plasma generation unit. The plasma generation unit 26 is, for example, a capacitively coupled plasma generation unit, an inductively coupled plasma generation unit, or a plasma generation unit that generates plasma with a surface wave such as a microwave.

This substrate processing apparatus 1 has a support table 10. Therefore, the substrate processing performed using the substrate processing apparatus 1 has improved in-plane uniformity.

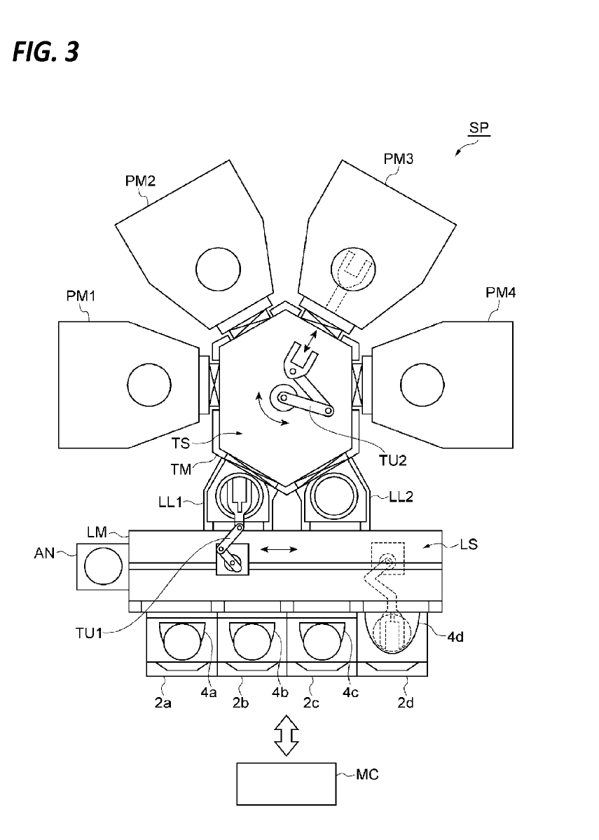

Hereinafter, a substrate processing apparatus according to an embodiment will be described. FIG. 3 is a view schematically illustrating a substrate processing system according to an embodiment. The substrate processing system SP illustrated in FIG. 3 includes tables 2a, 2b, 2c, 2d, containers 4a, 4b, 4c, 4d, a loader module LM, an aligner AN, load lock modules LL1, LL2, a transport module TM, and process modules PM1, PM2, PM3, PM4. In addition, the number of tables the number of containers, and the number of load lock modules of the substrate processing system SP may be arbitrary one or more. Further, the number of process modules of the substrate processing system SP may be arbitrary two or more.

The tables 2a, 2b, 2c, 2d are arranged along one edge of the loader module LM. The containers 4a, 4b, 4c, 4d are disposed on the tables 2a, 2b, 2c, 2d, respectively. The containers 4a, 4b, 4c, 4d are configured to accommodate a substrate therein. Each of the containers 4a, 4b, 4c, 4d may be a container called front-opening unified pod (FOUP).

The loader module LM provides a transport space LS therein. The pressure in the transport space LS is set to atmospheric pressure. The loader module LM has a transport device TU1. The transport device TU1 is, for example, an articulated robot. The transport device TU1 is provided to transport a substrate between each of the containers 4a, 4b, 4c, 4d and the aligner AN, between the aligner AN and each of the load lock modules LL1, LL2, between each of the containers 4a, 4b, 4c, 4d and each of load lock modules LL1, LL2, through the transport space LS. The aligner AN is connected to the loader module LM. The aligner AN calibrates the position of a substrate therein.

The load lock modules LL1, LL2 are provided between the loader module LM and the transport module TM. Each of the load lock modules LL1, LL2 provides a preliminary decompression chamber. A gate valve is provided between the preliminary decompression chamber of each of the load lock modules LL1, LL2 and the transport space LS.

The transport module TM provides a transport space TS therein. The transport space TS is configured to be capable of being decompressed. A gate valve is provided between the transport space TS of the transport module TM and the preliminary decompression chamber of each of the load lock modules LL1, LL2. The transport module TM has a transport device TU2. The transport device TU2 is, for example, an articulated robot. The transport device TU2 is configured to transport a substrate between the preliminary decompression chamber of each of the load lock modules LL1, LL2 and each of the process modules PM1, PM2, PM3, PM4, between any two of process modules PM1, PM2, PM3, PM4, through the transport space TS.

Each of the process modules PM1, PM2, PM3, PM4 is a device that executes a dedicated substrate processing. Each of the process modules PM1, PM2, PM3, PM4 is the substrate processing apparatus 1. That is, each of the process modules PM1, PM2, PM3, PM4 has the support table 10 and the chamber 18. The support table 10 is configured to support a substrate in the chamber 18. The internal space of the chamber 18 of each of the process modules PM1, PM2, PM3, PM4 is connected to the transport space TS through a gate valve.

The substrate processing system SP may further include a controller MC. The controller MC is configured to control each unit of the substrate processing system SP in each substrate processing performed in the substrate processing system SP. The control unit MC may be a computer device including a processor (e.g., a CPU), a storage device such as, for example, a memory, and a control signal input/output interface. The storage device stores a control program and recipe data. When the processor operates in accordance with the control program and the recipe data, a control signal is transmitted, and the substrate processing system SP operates according to the control signal.

In the substrate processing system SP, the shape of the surface region 14s of the support table 10 of each of the plurality of process modules, that is, the process modules PM1, PM2, PM3, PM4 is different from that of the surface region 14s of the support table 10 of at least one other process modules among the plurality of process modules. That is, each of the process modules PM1, PM2, PM3, PM4 supports, on the support table 10, a substrate having a shape of a rear surface different from that of the rear surface of a substrate processed in at least one other process module among these process modules. The shape of the surface region 14s of each of the process modules PM1, PM2, PM3, PM4 is formed so as to match or correspond to the shape of the rear surface 14r of a substrate to be supported. The shape of the rear surface of a substrate W to be processed may be measured, and the substrate W may be transported onto the support table 10 having the surface region 14s, of which the shape corresponds to or is similar to the measured shape of the rear surface of the support table 10 among the support tables 10 of the process modules PM1, PM2, PM3, PM4 so as to be processed.

According to this substrate processing system SP, the number of spots in the rear surface of the substrate, which are not in contact with the surface region 14s of the support table 10 of each of the plurality of process modules, decreases. Therefore, in each of the plurality of process modules, a substrate processing having high in-plane uniformity is capable of being realized.

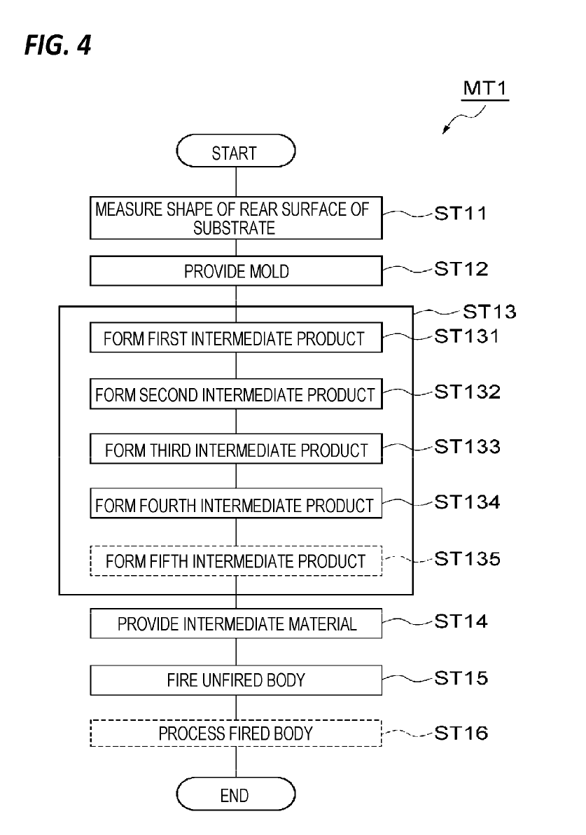

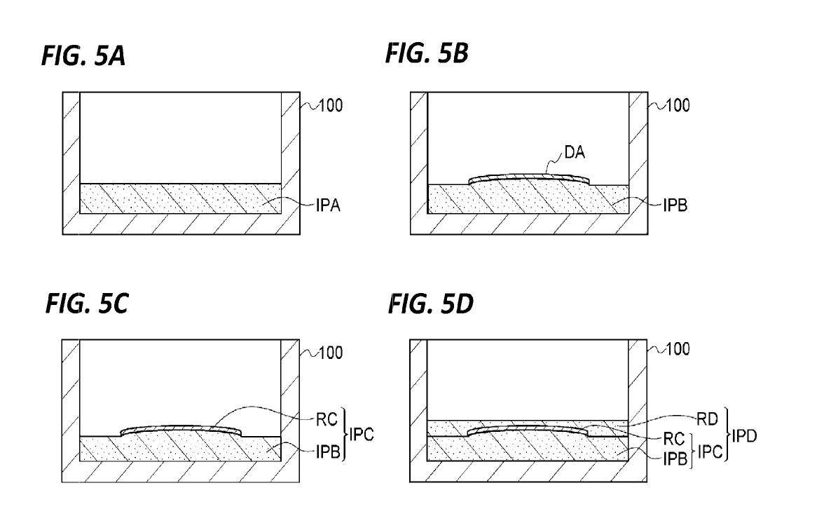

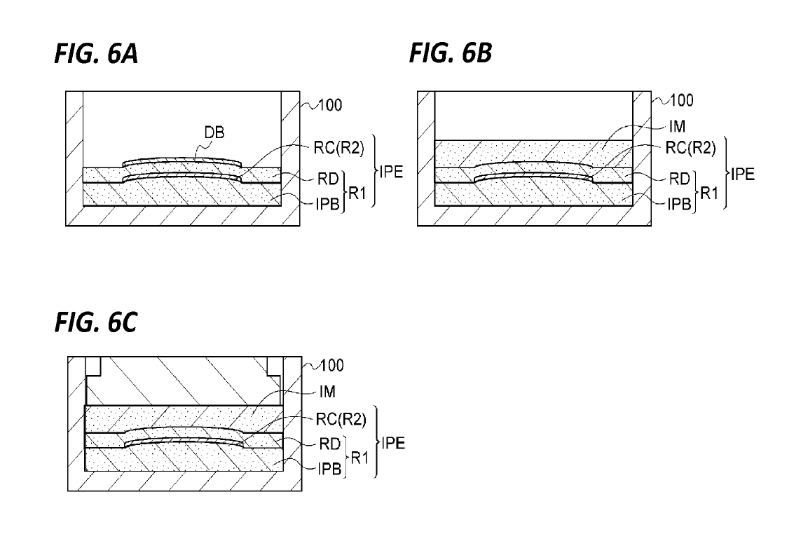

Hereinafter, various embodiments of a substrate support manufacturing method will be described. FIG. 4 is a flow flowchart illustrating an embodiment of a substrate manufacturing method. FIGS. 5A, 5B, 5C, and 5D and FIGS. 6A, 6B, and 6C are views each illustrating a product prepared in the steps of the method illustrated in FIG. 4. Method MT1 illustrated in FIG. 4 starts in step ST11. In step ST11, the shape of the rear surface Wr of a substrate W is measured. For measuring the shape of the rear surface Wr of the substrate W, any measurement device may be used.

In the subsequent step ST12, one or more molds used in the steps to be described later are prepared. The one or more molds are formed so as to have a shape that matches or corresponds to the shape of the rear surface Wr of the substrate W measured in step ST11. The method MT1 may not include step ST11. In this case, the surfaces of one or more molds are formed in step ST12 based on the measurement data of the shape of the rear surface Wr of a substrate W provided in advance.

In the subsequent step ST13, an unfired body is provided. The unfired body includes a first region R1 and a second region R2 (see, e.g., FIG. 6A). In one embodiment of step ST13, first, step ST131 is executed. In step ST131, raw material powder is provided in a container 100. In step ST131, a first intermediate product IPA is formed in the container 100 as illustrated in FIG. 5A. The first intermediate product IPA is composed of raw material powder provided in the container 100 in step ST131. The raw material powder used in step ST 131 is a dielectric material. By firing the dielectric material later, the main body 14m is formed.

In the subsequent step ST132, the mold DA is pressed against the first intermediate product IPA. The mold DA is formed in step ST12. In step ST132, as illustrated in FIG. 5B, a second intermediate product IPB containing an undulating surface is formed from the first intermediate product IPA in the container 100. Next, the mold DA is removed.

Next, step ST133 is executed. In step ST133, a conductive raw material is provided on the surface of the second intermediate product IPB in the container 100. The conductive raw material is provided so as to form a film on the undulating surface of the second intermediate product IPB. The conductive raw material is fired later so as to form the conductive film 14e. The raw material used in step ST133 is, for example, a conductive paste. Alternatively, the raw material used in step ST133 includes ceramic raw material powder and conductive metal raw material powder. When step ST133 is executed, a third intermediate product IPC is formed in the container 100 as illustrated in FIG. 5C. The third intermediate product IPC includes the second intermediate product IPB and a region RC formed of a conductive raw material on the surface of the second intermediate product IPB.

In the following step ST134, raw material powder is provided on the third intermediate product IPC in the container 100. The raw material powder used in step ST134 may be the same raw material powder as the raw material powder used in step ST131. In step ST134, as illustrated in FIG. 5D, a fourth intermediate product IPD is formed in the container 100. The fourth intermediate product IPD includes the third intermediate product IPC and a region RD formed of the raw meal powder on the third intermediate product IPC.

In step ST13 of an embodiment, step ST135 is subsequently executed. In step ST135, a mold DB is pressed in the region RD of the fourth intermediate product IPD. The mold DB is formed in step ST12. In step ST135, the mold DA may be used as the mold DB. Alternatively, in step ST135, a mold different from the mold DA may be used as the mold DB. In step ST135, as the mold DB is pressed in the region RD, a fifth intermediate product IPE, that is, an unfired body is formed in the container 100 as illustrated in FIG. 6A. The fifth intermediate product IPE includes the second intermediate product IPB, the region RC, and the region RD. In the fifth intermediate product IPE, the surface of the region RD has an undulation and is deformed on a surface extending along the region RC. In the fifth intermediate product IPE, i.e., the unfired body, the second intermediate product IPB and the region RD constitute the first region R1 and the region RC constitutes the second region R2. Next, the mold DB is removed, and step ST13 of an embodiment is terminated.

Next, step ST14 is executed. In step ST14, as illustrated in FIG. 6B, an intermediate material IM is provided on the fifth intermediate product IPE. The intermediate material IM is, for example, carbon powder. In the subsequent step ST15, an unfired body, i.e., the fifth intermediate product IPE, is fired together with the intermediate material IM. In step ST15, as illustrated in FIG. 6C, the unfired body is fired through a hot press method. That is, in step ST15, the unfired body is fired while being pressurized together with the intermediate material IM. When step ST15 is executed, the support 14 is formed. By firing the second intermediate product IPB and the region RD, i.e., the first region R1, the main body 14m is formed. In addition, the conductive film 14e is formed by firing the region RC, that is, the second region R2.

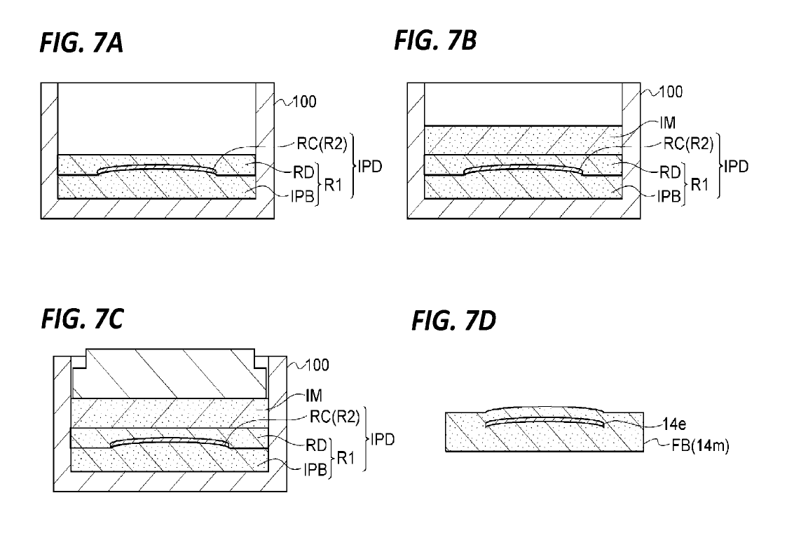

Hereinafter, reference is made to FIGS. 7A, 7B, 7C, and 7D together with FIG. 4. FIGS. 7A, 7B, 7C, and 7D are views each illustrating a product prepared in the steps of the method illustrated in FIG. 4. In another embodiment, step ST13 of method MT1 may not include step ST135. In this case, a fourth intermediate product IPD illustrated in FIG. 7A is an unfired body. In the fourth intermediate product IPD, i.e., an unfired body, the second intermediate product IPB and the region RD constitute the first region R1, and the region RC constitutes the second region R2.

After the fourth intermediate product IPD is formed in step ST134, step ST14 is executed. In step ST14, as illustrated in FIG. 7B, an intermediate material IM is provided on the fifth intermediate product IPE. Then, in step ST15, as illustrated in FIG. 7C, the unfired body, i.e., the fourth intermediate product IPD is fired together with the intermediate material IM through a hot press method. Through the firing in step ST15, a fired body FB is formed from the fourth intermediate product IPD. The region RC, i.e., the second region R2, becomes the conductive film 14e through the firing in step ST15. Next, step ST16 is executed. In step ST16, in the entire region of the fired body FB, the surface of the region formed through the firing of the first region R1 (the second intermediate product IPB and the region RD) is processed (e.g., machined). As a result of the processing executed in step ST16, the main body 14m is formed as illustrated in FIG. 7D. That is, the fired body FB is processed so as to provide the surface region 14s extending along the conductive film 14e.

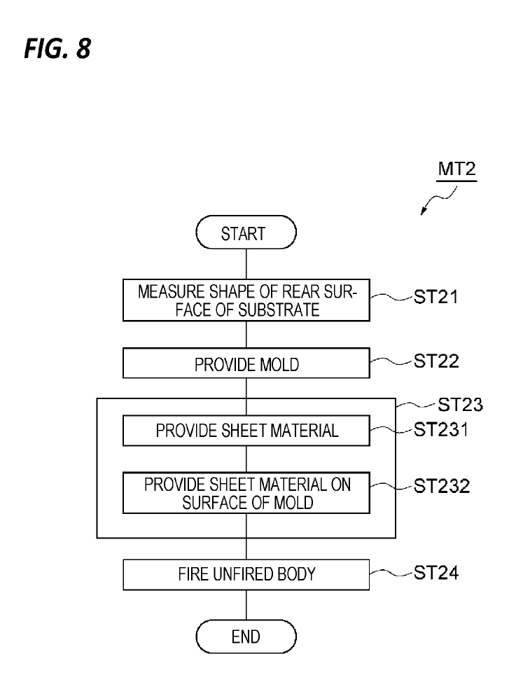

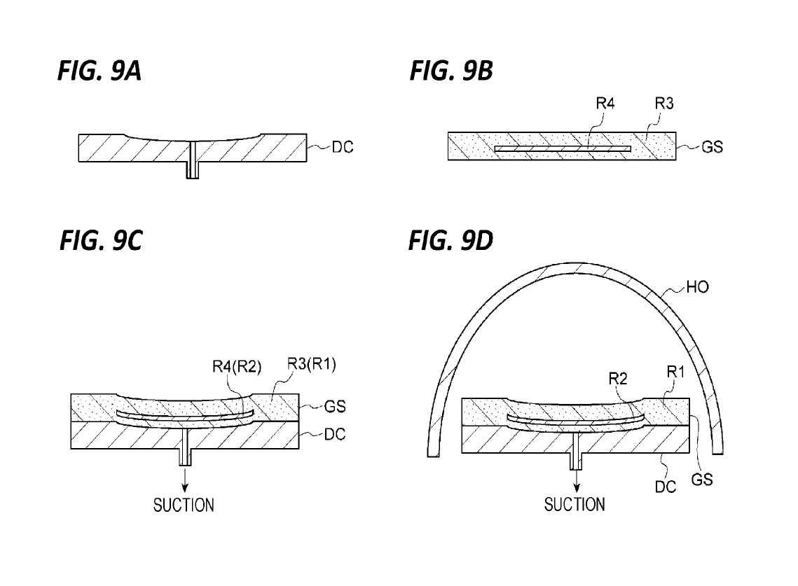

Hereinafter, reference is made to FIGS. 7A, 7B, 7C, and 7D together with FIG. 8. FIG. 8 is a flow chart illustrating another embodiment of the support manufacturing method. FIGS. 9A, 9B, 9C, and 9D are views each illustrating a product prepared in the steps of the method illustrated in FIG. 8. Method MT2 illustrated in FIG. 8 starts in step ST21. In step ST21, the shape of the rear surface Wr of a substrate W is measured. For measuring the shape of the rear surface Wr of the substrate W, any measurement device may be used.

In the subsequent step ST22, a mold DC used in a step to be described later is prepared (see, e.g., FIG. 9A). The mold DC is formed so as to have a shape that matches or corresponds to the shape of the rear surface Wr of the substrate W measured in step ST21. That is, the mold DC is formed so as to have an undulation corresponding to the undulation of the second region R2 to be described later. The method MT2 may not include step ST21. In this case, the surface of the mold DC is formed in step ST12 based on the measurement data of the shape of the rear surface Wr of a substrate W provided in advance.

In the subsequent step ST23, an unfired body is provided. Step ST 23 includes step ST231 and step ST232. In step ST231, a sheet material GS is provided. As illustrated in FIG. 9B, the sheet material GS includes a region R3 (third region) and a region R4 (fourth region). The region R3 is formed of a dielectric material. The dielectric material in the region R3 forms the main body 14m through the firing to be described later. The region R4 is provided in the region R3. The region R4 is conductive. In the region R3, the conductive film 14e is formed through the firing to be described later. In the sheet material GS, the region R4 does not have an undulation and is substantially flat.

In the subsequent step ST232, as illustrated in FIG. 9C, the sheet material GS is placed on the surface having an undulation of the mold DC. When the sheet material GS is placed on the surface of the mold DC, the sheet material GS is deformed according to the shape of the surface of the mold DC. That is, when the sheet material GS is placed on the surface of the mold DC in step ST232, the first region R1 is formed from the region R3, and the second region R2 is formed from the region R4. The second region R2 has an undulation. In addition, the surface of the first region R1 is spaced apart from the second region R2 and extends along the second region R2. The first region R1 provides a surface region having an undulation so as to have a substantially constant distance from the second region R2. The sheet material GS may be attracted to the mold DC by being sucked toward the mold DC. Alternatively, the sheet material GS may be attracted to the mold DC by electrostatic attraction.

As illustrated in FIG. 9D, in the subsequent step ST24, the sheet material GS is fired in a heating furnace HO in the state where the sheet material GS is placed on the mold DC. The firing in step ST24 is executed at normal pressure. The main body 14m is formed by firing the first region R1, and the conductive film 14e is formed by firing the second region R2.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A support table comprising:
a base; and
a support provided on the base,
wherein the support includes:
a main body formed of a dielectric material and including a surface region that is in contact with a rear surface of a substrate placed on the support and a rear surface opposite to the surface region; and
a conductive film formed in the main body,
the rear surface of the support is bonded to the base,
the conductive film is spaced apart from the surface region and having an undulation, and
the surface region extends along the conductive film.

2. The support table of claim 1, wherein the conductive film and the surface region extend to be at least partially curved.

3. The support table of claim 1, wherein the rear surface of the support and the base are bonded to each other via a bonding material.

4. The support table of claim 1, wherein a voltage is applied to the conductive film so as to generate an electrostatic attractive force.

5. The support table of claim 1, wherein the conductive film and the surface region extend to be at least partially curved,
the rear surface of the support and the base are bonded to each other via a bonding material, and
a voltage is applied to the conductive film so as to generate an electrostatic attractive force.

6. A substrate processing apparatus comprising:
a chamber; and
the support table of claim 1, the support table being configured to support a substrate in the chamber.

7. A substrate processing system comprising:
a plurality of process modules; and
a transport module including a transport device configured to transport a substrate to the plurality of process modules,
wherein each of the process modules includes a chamber and the support table of claim 1, the support table being configured to support a substrate in the chamber, and
the surface region of the support table of each of the plurality of process modules has a shape that is different from a shape of the surface region of the support table of at least one other process module among the plurality of process modules.

8. A method for manufacturing a substrate support, the method comprising:
providing an unfired body having a first region and a second region formed in the first region, the first region being formed of a dielectric raw material and the second region having conductivity and including an undulation; and
firing the unfired body.

9. The method of claim 8, wherein, in the firing the unfired body, the unfired body is fired through a hot press method,
the providing the unfired body includes:
forming a first intermediate product in the container by providing raw material powder as the dielectric raw material in the container;
forming a second intermediate product having a surface including an undulation by pressing a mold against the first intermediate product;
forming a third intermediate product by providing a conductive raw material on the surface of the second intermediate product in the container; and
forming a fourth intermediate product by providing the raw material powder on the surface of the third intermediate product in the container, and
the unfired body is the fourth intermediate product or is formed of the fourth intermediate product.

10. The method of claim 9, further comprising:
measuring a shape of a rear surface of a substrate,
wherein the surface of the mold is formed according to the measured shape.

11. The method of claim 9, wherein the surface of the mold is formed based on measured data of a shape of a rear surface of a substrate.

12. The method of claim 9, wherein the providing the unfired body further includes forming a fifth intermediate product in the container by pressing the mold or another mold against the fourth intermediate product,
the fifth intermediate product has a surface extending along a region formed of the conductive raw material, and
the unfired body is the fifth intermediate product.

13. The method of claim 9, wherein the unfired body is the fourth intermediate product,
the method further includes processing a surface of the fired body formed by firing the unfired body, and
in the processing the surface of the fired body, the surface of the fired body is processed so as to provide a surface region extending along a conductive film formed of the conductive raw material.

14. The method of claim 8, wherein, in the providing the unfired body, a sheet material including a third region formed of the dielectric raw material and a fourth region having conductivity and provided in the third region is provided,
the sheet material is placed on the surface of the mold such that the first region is formed from the third region and the second region is formed from the fourth region, and
the surface of the mold has an undulation corresponding to the undulation of the second region.

15. The method of claim 14, further comprising:
measuring a shape of a rear surface of a substrate,
wherein the surface of the mold is formed according to the measured shape.

16. The method of claim 14, wherein the surface of the mold is formed based on measured data of a shape of a rear surface of a substrate.
